(19) United States
(12) Patent Application Publication
(10) Pub. No.: US 2021/0323098 A1
(43) Pub. Date: Oct. 21, 2021

(54) WAFER PRODUCTION METHOD

(71) Applicant: DISCO CORPORATION, Tokyo (JP)

(72) Inventor: Asahi NOMOTO, Tokyo (JP)

(21) Appl. No.: 17/220,405

(22) Filed: Apr. 1, 2021

(30) Foreign Application Priority Data
Apr. 17, 2020 (JP) 2020-073786

(51) Int. Cl. B23K 26/402; B28D 5/04; B28D 5/00; B23K 26/02

(52) U.S. Cl. CPC B23K 26/402; B28D 5/04; B23K 2101/40; B23K 26/02; B28D 5/0011

(57) ABSTRACT

A wafer production method includes a separation layer forming step of positioning, from an end surface, the focal point of a laser beam with a wavelength having transmissibility with respect to a semiconductor ingot, at a depth corresponding to the thickness of a wafer to be produced, and irradiating the ingot with the laser beam to form a separation layer, a manufacturing history forming step of positioning the focal point of a laser beam with such a characteristic as not giving damage to a wafer to be produced next, to the upper surface of a region in which a device is not formed in the wafer to be produced, and irradiating the ingot with the laser beam to form a manufacturing history by ablation processing, and separating the wafer to be produced from the ingot using the separation layer as the point of origin, to produce the wafer.

### BACKGROUND OF THE INVENTION

### Field of the Invention

The present invention relates to a wafer production method for producing a wafer from a semiconductor ingot.

### Description of the Related Art

Devices such as integrated circuits (ICs), large-scale integrated circuits (LSIs), and light emitting diodes (LEDs) are formed with a functional layer stacked on a surface of a wafer that contains silicon (Si), sapphire (Al₂O₃), or the like as a material, in such a manner as to be marked out by plural planned dividing lines that intersect each other. Furthermore, power devices, LEDs, and so forth are formed with a functional layer stacked on a surface of a wafer that contains single-crystal silicon carbide (SiC) as a material, in such a manner as to be marked out by plural planned dividing lines that intersect each other. The wafer on which the devices are formed is divided into individual device chips through execution of processing along the planned dividing lines by a cutting apparatus or a laser processing apparatus, and the respective device chips obtained by the dividing are used for pieces of electrical equipment, such as mobile phones and personal computers.

The wafer on which the devices are formed is normally produced by thinly cutting a semiconductor ingot with a circular column shape by a wire saw. The front surface and the back surface of the cut wafer are finished into mirror surfaces by polishing (for example, refer to Japanese Patent Laid-open No. 2000-94221). However, when the semiconductor ingot is cut by the wire saw and the front surface and the back surface of the cut wafer are polished, there is a problem that a large part (70% to 80%) of the semiconductor ingot is discarded and this is uneconomical. In particular, in the case of the single-crystal SiC ingot, the hardness is high and cutting by the wire saw is thus difficult, requiring a considerable time. Thus, the productivity is low. In addition, the unit price of the ingot is high, and there is a problem in efficiently producing the wafer.

As such, the following technique has been proposed. The focal point of a laser beam with a wavelength having transmissibility with respect to single-crystal SiC is positioned inside a single-crystal SiC ingot, and the single-crystal SiC ingot is irradiated with the laser beam to form a separation layer at a planned cutting plane. In addition, after a manufacturing history is formed inside a wafer to be produced, the wafer is separated from the single-crystal SiC ingot along the planned cutting plane at which the separation layer is formed (for example, refer to Japanese Patent Laid-open No. 2019-29382).

### SUMMARY OF THE INVENTION

However, in the technique disclosed in Japanese Patent Laid-open No. 2019-29382, the laser beam to form the manufacturing history is transmitted through the separation layer and gives damage to the single-crystal SiC ingot. Thus, there is a problem that the quality of the wafer to be produced next is lowered.

Accordingly, an object of the present invention is to provide a wafer production method in which a laser beam to form a manufacturing history does not give damage to a semiconductor ingot.

In accordance with an aspect of the present invention, there is provided a wafer production method for producing a wafer from a semiconductor ingot. The wafer production method includes a planarization step of planarizing an end surface of the semiconductor ingot and a separation layer forming step of positioning, from the planarized end surface, the focal point of a laser beam with a wavelength having transmissibility with respect to the semiconductor ingot, at a depth corresponding to the thickness of a wafer to be produced, and irradiating the semiconductor ingot with the laser beam to form a separation layer. The wafer production method also includes a manufacturing history forming step of positioning the focal point of a laser beam with such a characteristic as not giving damage to a wafer to be produced next, to an upper surface of a region in which a device is not formed in the wafer to be produced, and irradiating the semiconductor ingot with the laser beam to form a manufacturing history by ablation processing and a wafer production step of separating the wafer to be produced, from the semiconductor ingot with use of the separation layer as the point of origin, to produce the wafer.

Preferably, in the manufacturing history formed in the manufacturing history forming step, any of a lot number of the semiconductor ingot, the order of the wafer to be produced, a manufacturing date, a manufacturing plant, and a type of equipment that contributes to production is included. Preferably, the semiconductor ingot is a single-crystal SiC ingot having a first end surface, a second end surface on the opposite side of the first end surface, a c-axis that reaches the second end surface from the first end surface, and a c-plane orthogonal to the c-axis, the c-axis is inclined with respect to a perpendicular line of the first end surface, and an off-angle is formed by the c-plane and the first end surface. In the separation layer forming step, the focal point of a pulse laser beam with a wavelength having transmissibility with respect to the single-crystal SiC ingot is positioned at the depth corresponding to the thickness of the wafer to be produced, from the first end surface, the single-crystal SiC ingot and the focal point are relatively moved in a direction orthogonal to a direction in which the off-angle is formed, to form a straight-line-shaped modified layer formed through separation of SiC into Si and carbon (C), absorption of the pulse laser beam with which irradiation is to be executed next by previously-formed C, and separation of SiC into Si and C in a chain-reaction manner and cracks, and the single-crystal SiC ingot and the focal point are relatively moved in the direction in which the off-angle is formed, to execute indexing by a predetermined amount and form the separation layer.

According to the wafer production method of the present invention, the laser beam to form the manufacturing history is sufficiently absorbed at the upper surface of the semiconductor ingot, and there is hardly any leak light to the inside of the semiconductor ingot. Thus, the situation in which the leak light gives damage to the semiconductor ingot does not occur, and the problem that the quality of the wafer to be produced next is lowered is eliminated.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a front view of a semiconductor ingot;

FIG. 1B is a plan view of the semiconductor ingot;

FIG. 2A is a perspective view of the semiconductor ingot and a substrate;

FIG. 2B is a perspective view illustrating the state in which the substrate is mounted on the semiconductor ingot;

FIG. 3 is a perspective view illustrating the state in which the semiconductor ingot is placed over a chuck table of a laser processing apparatus;

FIG. 4A is a perspective view illustrating the state in which a separation layer forming step is being executed;

FIG. 4B is a front view illustrating the state in which the separation layer forming step is being executed;

FIG. 5A is a plan view of the semiconductor ingot in which a separation layer is formed;

FIG. 5B is a sectional view along line B-B in FIG. 5A;

FIG. 6A is a perspective view illustrating the state in which a manufacturing history forming step is being executed;

FIG. 6B is a front view illustrating the state in which the manufacturing history forming step is being executed;

FIG. 7 is a perspective view of a separating apparatus;

FIG. 8 is a sectional view of the separating apparatus illustrating the state in which a wafer production step is being executed;

FIG. 9 is a perspective view illustrating the state in which a wafer has been separated from the semiconductor ingot; and

FIG. 10 is a perspective view illustrating the state in which a planarization step is being executed.

### DETAILED DESCRIPTION OF THE PREFERRED EMBODIMENT

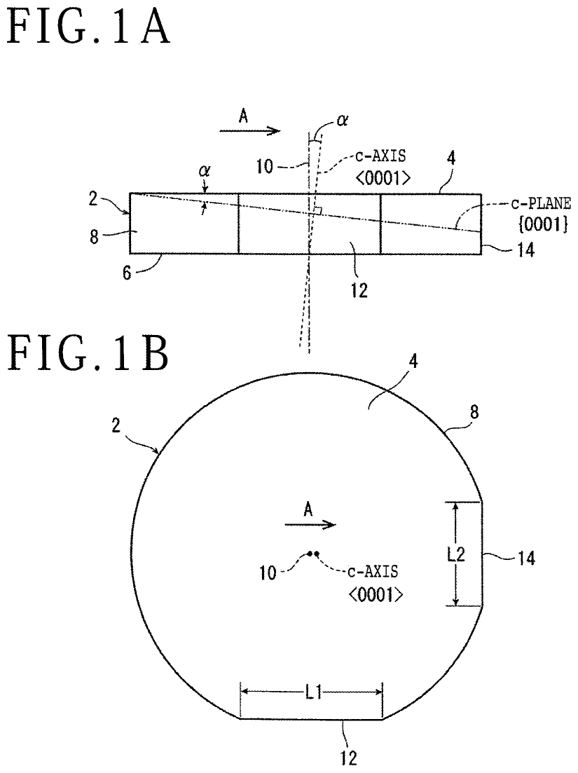

A preferred embodiment of a wafer production method of the present invention will be described below with reference to the drawings. In FIG. 1A and FIG. 1B, a circular columnar semiconductor ingot (hereinafter, abbreviated simply as an ingot) 2 that can be used for the wafer production method of the present invention is illustrated. The ingot 2 of the present embodiment is formed from hexagonal single-crystal SiC. The ingot 2 has a circular first end surface 4, a circular second end surface 6 on the opposite side of the first end surface 4, a circumferential surface 8 located between the first end surface 4 and the second end surface 6, a c-axis (<0001>direction) that reaches the second end surface 6 from the first end surface 4, and a c-plane ({0001} plane) orthogonal to the c-axis.

In the ingot 2, the c-axis is inclined with respect to a perpendicular line 10 to the first end surface 4, and an off-angle α (for example, α=1, 3, or 6 degrees) is formed by the c-plane and the first end surface 4. The direction in which the off-angle α is formed is indicated by an arrow A in FIG. 1. Moreover, in the circumferential surface 8 of the ingot 2, a first orientation flat 12 and a second orientation flat 14 that both indicate the crystal orientation and have a rectangular shape are formed. The first orientation flat 12 is parallel to the direction A in which the off-angle α is formed, and the second orientation flat 14 is orthogonal to the direction A in which the off-angle α is formed. As illustrated in FIG. 1B, as viewed from the upper side, a length L2 of the second orientation flat 14 is shorter than a length L1 of the first orientation flat 12 (L2<L1).

The ingot that can be used for the wafer production method of the present invention is not limited to the above-described ingot 2. For example, the ingot may be a SiC ingot in which the c-axis is not inclined with respect to the perpendicular line of the first end surface and the off-angle α between the c-plane and the first end surface is 0 degrees (that is, the perpendicular line of the first end surface corresponds with the c-axis), or may be an ingot formed from a material other than single-crystal SiC, such as Si or gallium nitride (GaN).

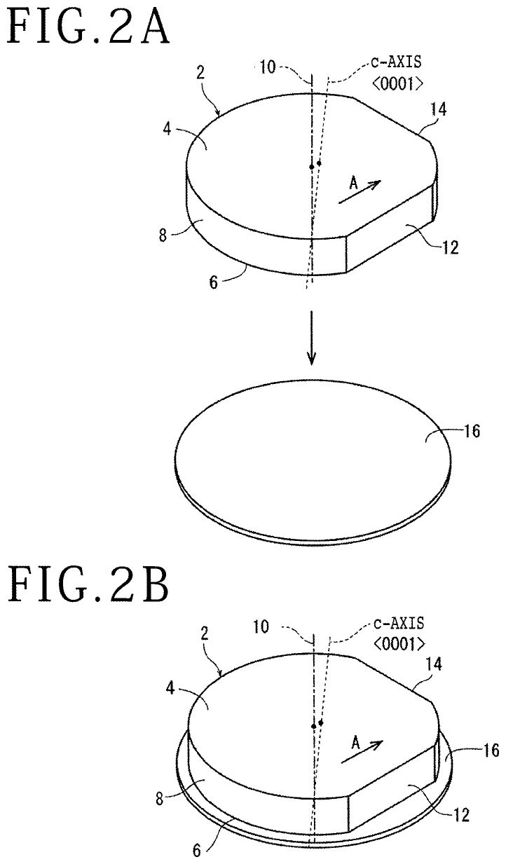

In the present embodiment, first, as illustrated in FIG. 2A, a substrate 16 with a circular plate shape is bonded to the second end surface 6 of the ingot 2 with the intermediary of an appropriate adhesive. The purpose of bonding the substrate 16 to the ingot 2 is to suck and hold the ingot 2 in which the first orientation flat 12 and the second orientation flat 14 are formed, with a predetermined suction force by a circular suction-adhesion chuck of each apparatus to be described later.

The diameter of the substrate 16 is slightly larger than the diameter of the suction-adhesion chuck of each apparatus to be described later. Thus, the suction-adhesion chuck is covered by the substrate 16 when the ingot 2 is placed over the suction-adhesion chuck with the substrate 16 oriented downward. Thus, the ingot 2 in which the first orientation flat 12 and the second orientation flat 14 are formed can be sucked and held by the suction-adhesion chuck with a predetermined suction force.

In the case in which the diameter of the ingot 2 is larger than the suction-adhesion chuck and the whole of the upper surface of the suction-adhesion chuck is covered by the ingot 2 when the ingot 2 is placed over the suction-adhesion chuck, air is not sucked from the exposed part of the suction-adhesion chuck in suction by the suction-adhesion chuck, and suction adhesion of the ingot 2 with a predetermined suction force is enabled by the suction-adhesion chuck. Therefore, the substrate 16 does not need to be mounted on the ingot 2.

After the substrate 16 is mounted on the ingot 2, a separation layer forming step of positioning, from a planarized end surface, the focal point of a laser beam with a wavelength having transmissibility with respect to the ingot 2, at a depth corresponding to the thickness of a wafer to be produced, and irradiating the ingot 2 with the laser beam to form a separation layer is executed. In the ingot 2, normally, the first end surface 4 and the second end surface 6 are planarized at such a degree that incidence of the laser beam in the separation layer forming step is not precluded. Thus, before the first separation layer forming step is executed on the ingot 2, a planarization step of planarizing the end surface of the ingot 2 does not need to be executed.

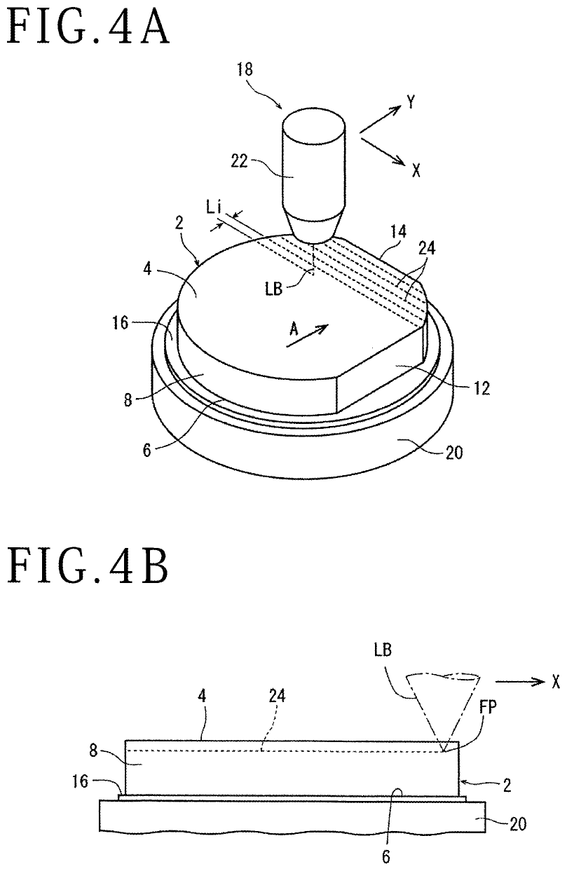

The separation layer forming step can be executed by using a laser processing apparatus 18 partly illustrated in FIG. 4A, for example. The laser processing apparatus 18 includes a chuck table 20 that sucks and holds the ingot 2 and a light collector 22 (see FIG. 4A) that irradiates the ingot 2 sucked and held by the chuck table 20 with a pulse laser beam LB.

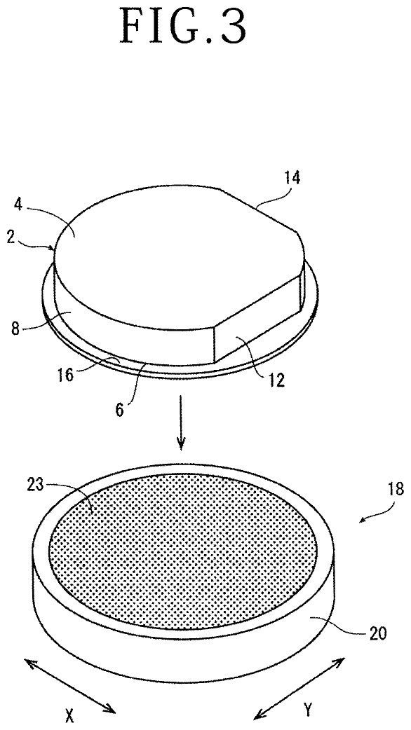

At the upper end part of the chuck table 20, a porous circular suction-adhesion chuck 23 (see FIG. 3) connected to suction means (not illustrated) is disposed. The chuck table 20 sucks and holds the ingot 2 placed over the upper surface, by producing a suction force at the upper surface of the suction-adhesion chuck 23 by the suction means. The chuck table 20 is configured rotatably around an axis line that extends in the upward-downward direction and is configured to be capable of advancing and receding in each of an X-axis direction indicated by an arrow X in FIG. 3 and a Y-axis direction (direction indicated by an arrow Y in FIG. 3) orthogonal to the X-axis direction. The light collector 22 is configured to be capable of advancing and receding in the X-axis direction and the Y-axis direction. The XY-plane defined by the X-axis direction and the Y-axis direction is substantially horizontal.

As illustrated in FIG. 3, in the separation layer forming step, first, the ingot 2 is sucked and held by the upper surface of the chuck table 20 with the substrate 16 oriented downward. Subsequently, the ingot 2 is imaged from the upper side by an imaging unit (not illustrated) of the laser processing apparatus 18. Then, based on an image of the ingot 2 imaged by the imaging unit, the orientation of the ingot 2 is adjusted to a predetermined orientation and the positions in the XY-plane regarding the ingot 2 and the light collector 22 are adjusted. When the orientation of the ingot 2 is adjusted to the predetermined orientation, as illustrated in FIG. 4A, the second orientation flat 14 is aligned with the X-axis direction. The direction orthogonal to the direction A in which the off-angle α is formed is thereby aligned with the X-axis direction, and the direction A in which the off-angle α is formed is aligned with the Y-axis direction.

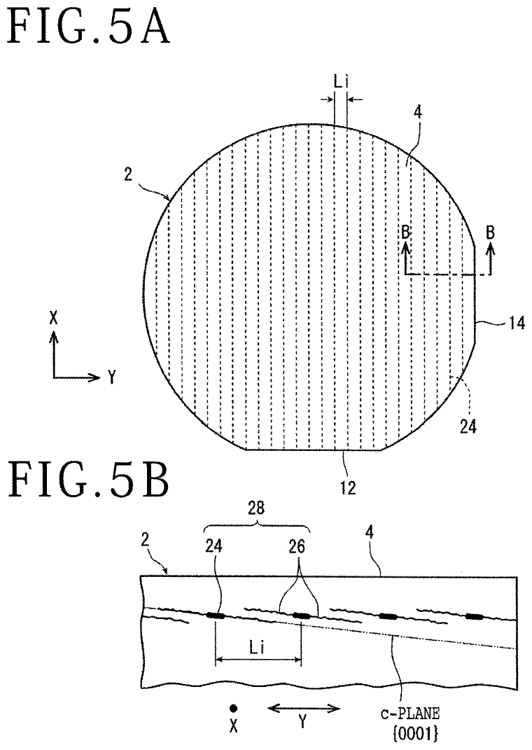

Next, a focal point FP (see FIG. 4B) is positioned at a depth (for example, 700 μm) corresponding to the thickness of the wafer to be produced, from the first end surface 4 of the ingot 2. Subsequently, while the ingot 2 and the light collector 22 are relatively moved in the X-axis direction at a predetermined feed rate, the ingot 2 is irradiated with the pulse laser beam LB with a wavelength having transmissibility with respect to the ingot 2 from the light collector 22. As a result, as illustrated in FIG. 5, the modified layer 24 arising from separation of SiC into Si and C, absorption of the pulse laser beam LB with which irradiation is to be executed next by previously-formed C, and separation of SiC into Si and C in a chain-reaction manner is continuously formed in a straight line manner in the X-axis direction. In addition, cracks 26 that isotropically extend along the c-plane from the modified layer 24 are formed.

Subsequently, indexing feed of the ingot 2 and the focal point FP is relatively executed in the Y-axis direction by a predetermined indexing amount Li in a range in which the width of the cracks 26 is not exceeded. Then, by alternately repeating irradiation with the pulse laser beam LB and indexing feed, plural modified layers 24 that extend in the X-axis direction are formed at intervals of the predetermined indexing amount Li in the Y-axis direction. In addition, the cracks 26 that isotropically extend along the c-plane from the modified layers 24 are sequentially formed, and the cracks 26 that are adjacent in the Y-axis direction are caused to overlap as viewed in the upward-downward direction. Due to this, a separation layer 28 that includes the plural modified layers 24 and the cracks 26 and at which the strength for separating a wafer from the ingot 2 is lowered can be formed at the depth corresponding to the thickness of the wafer to be produced, from the first end surface 4 of the ingot 2. The separation layer forming step can be executed under the following processing conditions, for example.

Wavelength of pulse laser beam: 1,064 nm

Repetition frequency: 120 kHz

Average output power: 8.0 W

Diameter of focal point: 1 μm

Indexing amount: 250 to 400 μm

Feed rate: 934 mm/s

After the separation layer forming step is executed, a manufacturing history forming step of positioning the focal point of a laser beam with such a characteristic as not giving damage to the wafer to be produced next, to the upper surface of a region in which a device is not formed in the wafer to be produced, and irradiating the ingot 2 with the laser beam to form a manufacturing history by ablation processing is executed.

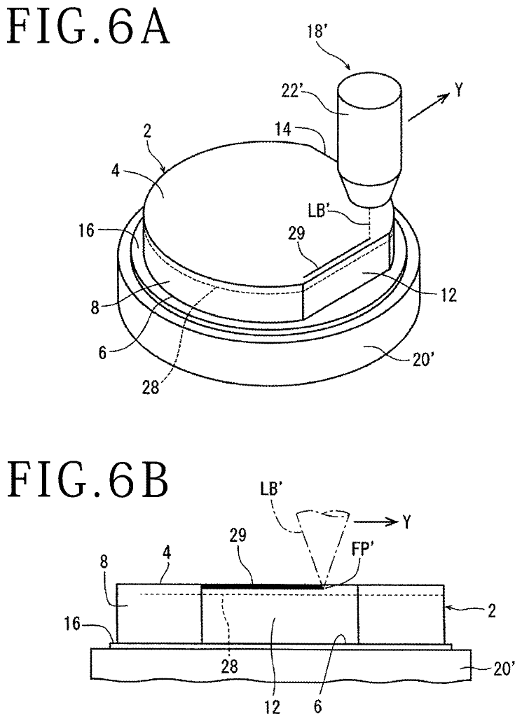

The manufacturing history forming step can be executed by using a laser processing apparatus 18′ partly illustrated in FIG. 6A, for example. The laser processing apparatus 18′ for executing the manufacturing history forming step includes a chuck table 20′ that sucks and holds the ingot 2 and a light collector 22′ that irradiates the ingot 2 held by the chuck table 20′ with a pulse laser beam LB′ and has substantially the same configuration as the laser processing apparatus 18 that can execute the separation layer forming step. However, the laser processing apparatus 18′ is configured to irradiate a workpiece with the pulse laser beam LB′ different from the pulse laser beam LB of the laser processing apparatus 18.

The explanation will be continued with reference to FIG. 6A and FIG. 6B. In the manufacturing history forming step, first, the ingot 2 is sucked and held by the upper surface of the chuck table 20′ with the substrate 16 oriented downward. Next, the ingot 2 is imaged by an imaging unit (not illustrated) of the laser processing apparatus 18′, and the position of the light collector 22′ is adjusted based on an image of the ingot 2 imaged by the imaging unit.

Then, a focal point FP′ of the pulse laser beam LB′ with such a characteristic as not giving damage to the wafer to be produced next is positioned to the upper surface (in the present embodiment, first end surface 4) of a peripheral surplus region in which a device is not formed in the wafer to be produced. Subsequently, the ingot 2 is irradiated with the pulse laser beam LB′ from the light collector 22′ while the ingot 2 and the focal point FP′ are relatively moved as appropriate. Ablation processing can thereby be executed on the upper surface of the peripheral surplus region in which a device is not formed in the wafer to be produced, and a manufacturing history 29 that can be configured in the form of a barcode can be formed.

The pulse laser beam LB′ in the manufacturing history forming step is a laser beam for which the wavelength, the average output power, and so forth have been controlled in order to cause the laser beam to be sufficiently absorbed at the upper surface of the ingot 2 to which the focal point FP′ is positioned. By using such a pulse laser beam LB′, the manufacturing history 29 can be formed at the upper surface of the ingot 2 by ablation processing. Meanwhile, there is hardly any leak light to the part on the lower side relative to the separation layer 28 in the ingot 2, giving no damage to the wafer to be produced next. As the pulse laser beam LB′ in the manufacturing history forming step, a laser beam having the following characteristics can be used, for example.

Wavelength: 355 nm

Repetition frequency: 40 kHz

Average output power: 1.1 W

Diameter of focal point: 46 μm

In the manufacturing history 29 formed in the manufacturing history forming step, any of the lot number of the ingot 2, the order of the wafer to be produced from the ingot 2, the manufacturing date of the wafer, the manufacturing plant of the wafer, and the type of equipment that contributes to production of the wafer is included. In the present embodiment, the manufacturing history 29 is formed along the first orientation flat 12. However, as long as the manufacturing history 29 is formed at the upper surface of a region in which a device is not formed in the wafer to be produced, the manufacturing history 29 may be formed along the second orientation flat 14, or the manufacturing history 29 may be formed along an arc-shaped peripheral edge. Furthermore, the depth of the manufacturing history 29 is set to such a depth (for example, approximately 200 to 300 μm) that the manufacturing history 29 is not removed when the front surface and the back surface of the wafer separated from the ingot 2 are ground and polished and the wafer is thinned.

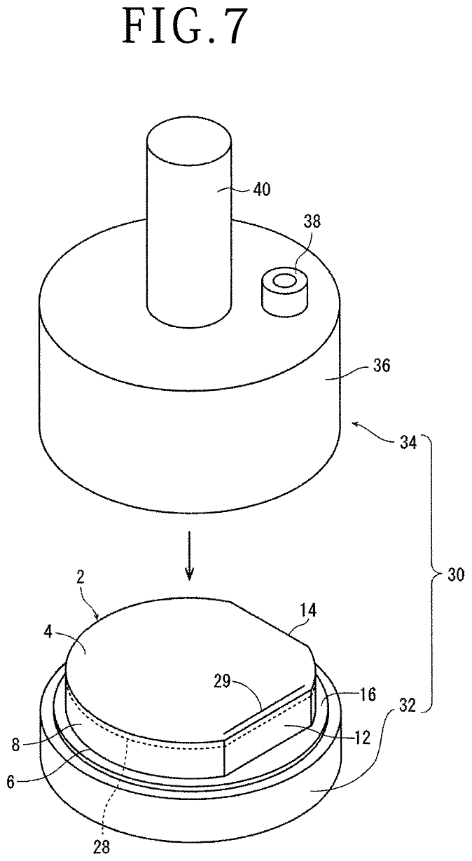

After the manufacturing history forming step is executed, a wafer production step of separating the wafer to be produced, from the ingot 2 with use of the separation layer 28 as the point of origin, to produce the wafer is executed. The wafer production step can be executed by using a separating apparatus 30 partly illustrated in FIG. 7 to FIG. 9, for example. The separating apparatus 30 includes a chuck table 32 that sucks and holds the ingot 2 and separating means 34 that holds the upper surface of the ingot 2 held by the chuck table 32 and that separates a wafer from the ingot 2 with use of the separation layer 28 as the point of origin.

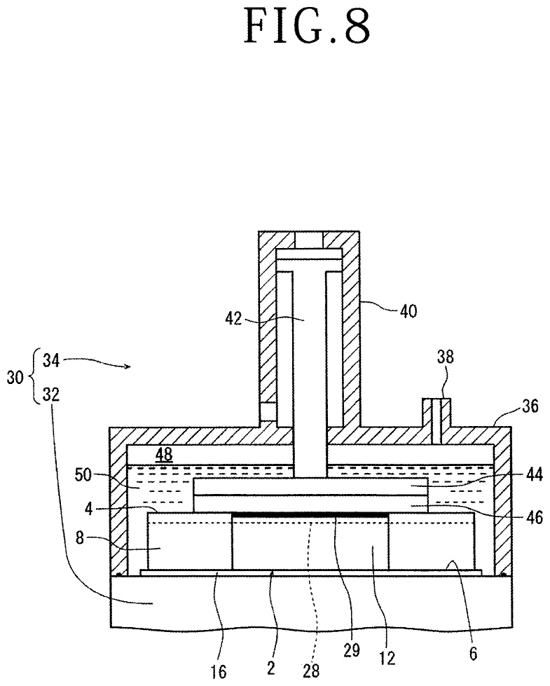

The separating means 34 includes a liquid tank body 36 that can rise and lower and that houses liquid in cooperation with the chuck table 32 when a wafer is separated from the ingot 2. A liquid supply part 38 connected to liquid supply means (not illustrated) is annexed to the liquid tank body 36, and an air cylinder 40 is mounted on the liquid tank body 36. As illustrated in FIG. 8, an ultrasonic oscillation component 44 is fixed to the lower end part of a rod 42 of the air cylinder 40, and a suction-adhesion piece 46 is fixed to the lower surface of the ultrasonic oscillation component 44.

As illustrated in FIG. 7, in the wafer production step, first, the ingot 2 is sucked and held by the upper surface of the chuck table 32 with the substrate 16 oriented downward. Next, as illustrated in FIG. 8, the liquid tank body 36 is lowered, and the lower end of the liquid tank body 36 is brought into tight contact with the upper surface of the chuck table 32. Subsequently, the first end surface 4 of the ingot 2 is sucked and held by the suction-adhesion piece 46.

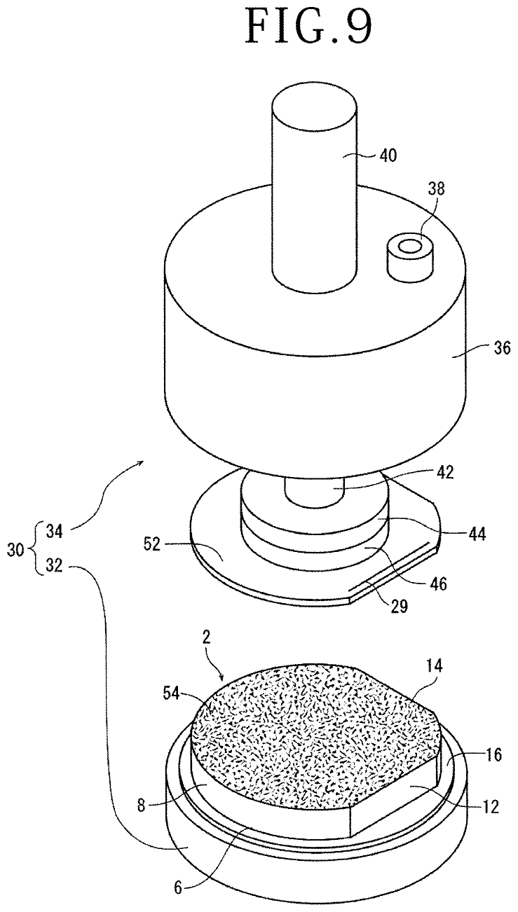

Then, a liquid 50 (for example, water) is supplied from the liquid supply part 38 to a liquid housing space 48 defined by the upper surface of the chuck table 32 and the inner surface of the liquid tank body 36. Following this, ultrasonic waves are oscillated from the ultrasonic oscillation component 44. As a result, the separation layer 28 is stimulated, and the cracks 26 are extended to break the separation layer 28. Subsequently, by raising the liquid tank body 36 in the state in which the ingot 2 is sucked and held by the suction-adhesion piece 46, as illustrated in FIG. 9, a wafer 52 having the manufacturing history 29 can be separated and produced from the ingot 2 with use of the separation layer 28 as the point of origin.

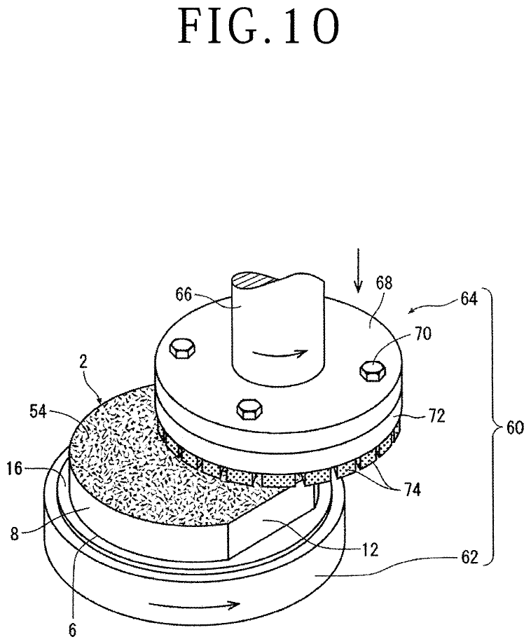

After the wafer production step is executed, a planarization step of planarizing an end surface (separation surface 54) of the ingot 2 is executed. The planarization step can be executed by using a grinding apparatus 60 partly illustrated in FIG. 10, for example. The grinding apparatus 60 includes a chuck table 62 that sucks and holds the ingot 2 and grinding means 64 that grinds and planarizes an end surface of the ingot 2 sucked and held by the chuck table 62.

The chuck table 62 that sucks and holds the ingot 2 at the upper surface is rotatably configured. The grinding means 64 includes a spindle 66 configured rotatably around the axial center along the upward-downward direction and a wheel mount 68 fixed to the lower end of the spindle 66. An annular grinding wheel 72 is fixed to the lower surface of the wheel mount 68 by bolts 70. To the outer circumferential edge part of the lower surface of the grinding wheel 72, plural grinding abrasive stones 74 annularly disposed at intervals in the circumferential direction are fixed.

The explanation will be continued with reference to FIG. 10. In the planarization step, first, the ingot 2 is sucked and held by the upper surface of the chuck table 62 with the substrate 16 oriented downward. Next, the chuck table 62 is rotated, and the spindle 66 is rotated. Then, the spindle 66 is lowered, and the grinding abrasive stones 74 are brought into contact with the separation surface 54. Thereafter, the spindle 66 is lowered at a predetermined grinding feed rate. As a result, the separation surface 54 of the ingot 2 can be ground and planarized at such a degree that incidence of the pulse laser beam LB in the separation layer forming step and the pulse laser beam LB′ in the manufacturing history forming step is not precluded. Furthermore, plural wafers 52 having the manufacturing history 29 are produced from the ingot 2 by repetitively executing the separation layer forming step, the manufacturing history forming step, the wafer production step, and the planarization step.

As described above, the wafer production method of the present embodiment includes at least the planarization step of planarizing an end surface of the ingot 2, the separation layer forming step of positioning, from the planarized end surface, the focal point FP of the pulse laser beam LB with a wavelength having transmissibility with respect to the ingot 2, at the depth corresponding to the thickness of the wafer to be produced, and irradiating the ingot 2 with the pulse laser beam LB to form the separation layer 28, the manufacturing history forming step of positioning the focal point FP′ of the pulse laser beam LB′ with such a characteristic as not giving damage to the wafer to be produced next, to the upper surface of a region in which a device is not formed in the wafer to be produced, and irradiating the ingot 2 with the pulse laser beam LB′ to form the manufacturing history 29 by ablation processing, and the wafer production step of separating the wafer to be produced, from the ingot 2 with use of the separation layer 28 as the point of origin, to produce the wafer. Thus, the pulse laser beam LB′ to form the manufacturing history 29 is sufficiently absorbed at the upper surface of the ingot 2, and there is hardly any leak light to the inside of the ingot 2. Consequently, the situation in which the leak light gives damage to the ingot 2 does not occur, and the problem that the quality of the wafer to be produced next is lowered is eliminated.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer production method for producing a wafer from a semiconductor ingot, the wafer production method comprising:
a planarization step of planarizing an end surface of the semiconductor ingot;
a separation layer forming step of positioning, from the planarized end surface, a focal point of a laser beam with a wavelength having transmissibility with respect to the semiconductor ingot, at a depth corresponding to a thickness of a wafer to be produced, and irradiating the semiconductor ingot with the laser beam to form a separation layer;
a manufacturing history forming step of positioning a focal point of a laser beam with such a characteristic as not giving damage to a wafer to be produced next, to an upper surface of a region in which a device is not formed in the wafer to be produced, and irradiating the semiconductor ingot with the laser beam to form a manufacturing history by ablation processing; and
a wafer production step of separating the wafer to be produced, from the semiconductor ingot with use of the separation layer as a point of origin, to produce the wafer.

2. The wafer production method according to claim 1, wherein
the manufacturing history formed in the manufacturing history forming step includes any of a lot number of the semiconductor ingot, order of the wafer to be produced, a manufacturing date, a manufacturing plant, and a type of equipment that contributes to production.

3. The wafer production method according to claim 1, wherein
the semiconductor ingot is a single-crystal silicon carbide ingot having a first end surface, a second end surface on an opposite side of the first end surface, a c-axis that reaches the second end surface from the first end surface, and a c-plane orthogonal to the c-axis, the c-axis is inclined with respect to a perpendicular line of the first end surface, and an off-angle is formed by the c-plane and the first end surface, and
in the separation layer forming step,
a focal point of a pulse laser beam with a wavelength having transmissibility with respect to the single-crystal silicon carbide ingot is positioned at the depth corresponding to the thickness of the wafer to be produced, from the first end surface, the single-crystal silicon carbide ingot and the focal point are relatively moved in a direction orthogonal to a direction in which the off-angle is formed, to form a straight-line-shaped modified layer formed through separation of silicon carbide into silicon and carbon, absorption of the pulse laser beam with which irradiation is to be executed next by previously-formed carbon, and separation of silicon carbide into silicon and carbon in a chain-reaction manner and cracks that extend along the c-plane from the modified layer, and the single-crystal silicon carbide ingot and the focal point are relatively moved in the direction in which the off-angle is formed, to execute indexing by a predetermined amount and form the separation layer.
